(19) United States
(12) Patent Application Publication
(10) Pub. No.: US 2015/0221582 A1
(43) Pub. Date: Aug. 6, 2015

(54) CONNECTOR FRAME AND SEMICONDUCTOR DEVICE

(71) Applicant: KABUSHIKI KAISHA TOSHIBA, Tokyo (JP)

(72) Inventor: Takeshi Miyakawa, Kanazawa (JP)

(21) Appl. No.: 14/456,722

(22) Filed: Aug. 11, 2014

(30) Foreign Application Priority Data
Jan. 31, 2014 (JP) 2014-017327

(51) Int. Cl. H01L 23/495; H01B 5/00; H01B 1/02; H01L 23/31; H01L 23/00

(52) U.S. Cl. CPC H01L 23/49537; H01L 23/49503; H01L 23/49541; H01L 23/3107; H01L 24/41; H01B 1/02; H01B 5/00; H01L 2224/29147; H01L 2224/32245; H01L 2924/20645; H01L 2924/20646; H01L 2924/20647; H01L 2924/20648; H01L 2924/20649; H01L 2924/2065

(57) ABSTRACT

According to one embodiment, a connector frame includes a frame part, a first connector projected from the frame part and integrated with the frame part, and a second connector projected from the frame part and integrated with the frame part. The first connector includes a first portion and a second portion provided between the first portion and the frame part. The second portion is thinner than the first portion. The second connector is as thick as the second portion of the first connector.

### CROSS-REFERENCE TO RELATED APPLICATION

This application is based upon and claims the benefit of priority from Japanese Patent Application No.2014-017327, filed on Jan. 31, 2014; the entire contents of which are incorporated herein by reference.

### FIELD

Embodiments described herein relate generally to a connector frame and a semiconductor device.

### BACKGROUND

Recently, as a connection structure between the chip and the external lead in power semiconductor devices, a structure based on a plate-like connector or strap of copper or the like has been proposed instead of wire bonding for the purpose of lower resistance. Many products based on this structure have also been available.

Furthermore, a structure has been proposed in which the connector mounted on the chip is exposed from the resin to dissipate heat from both the package lower surface on the mounting substrate side and the package upper surface. The portion exposed from the package upper surface is preferably thicker from the viewpoint of heat dissipation performance. On the other hand, the portion of the connector extending toward the lead and connected to the lead is not located directly above the chip, and hence does not significantly contribute to heat dissipation. Thus, this portion does not need to be thickened, but may be as thick as the existing lead frame. Furthermore, the necessity of thickening the gate connector is also low, because a smaller current flows in the gate connector than in the source connector.

### BRIEF DESCRIPTION OF THE DRAWINGS

FIG. 1 is a schematic sectional view of a semiconductor device of an embodiment;

FIGS. 2A and 2B are schematic top views of the semiconductor device of the embodiment;

FIGS. 3A and 3B are schematic plan views of a semiconductor chip of the embodiment;

FIG. 4 is a schematic plan view of a connector frame of the embodiment;

FIG. 5A is a schematic plan view of a first connector and a second connector of the embodiment, FIG. 5B is a schematic sectional view of the first connector, and FIG. 5C is a schematic sectional view of the second connector;

FIG. 6A is a schematic plan view of a metal plate fabricating the connector frame of the embodiment, and FIG. 6B is a schematic sectional view of the metal plate;

FIG. 7 is a schematic sectional view of another example of the semiconductor device of the embodiment;

FIG. 8A is a schematic plan view of another example of the first connector and the second connector of the embodiment, FIG. 8B is a schematic sectional view of the first connector, and FIG. 8C is a schematic sectional view of the second connector;

FIG. 9 is a schematic sectional view of another example of the semiconductor device of the embodiment;

FIG. 10A is a schematic plan view of another example of the first connector and the second connector of the embodiment, FIG. 10B is a schematic sectional view of the first connector, and FIG. 10C is a schematic sectional view of the second connector; and

FIG. 11 is a schematic top view of another example of the semiconductor device of the embodiment.

### DETAILED DESCRIPTION

According to one embodiment, a connector frame includes a frame part, a first connector projected from the frame part and integrated with the frame part, and a second connector projected from the frame part and integrated with the frame part. The first connector includes a first portion and a second portion provided between the first portion and the frame part. The second portion is thinner than the first portion. The second connector is as thick as the second portion of the first connector.

Embodiments will now be described with reference to the drawings. In the drawings, like elements are labeled with like reference numerals.

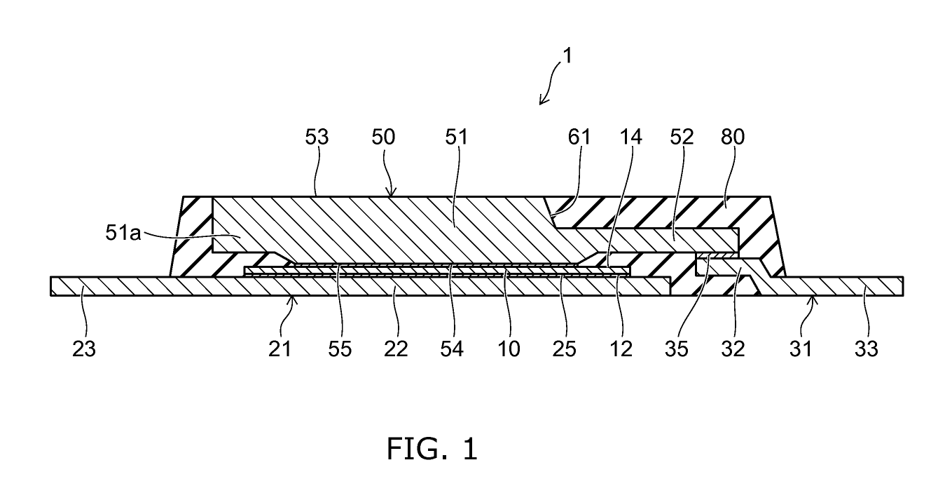

FIG. 1 is a schematic sectional view of a semiconductor device 1 of an embodiment.

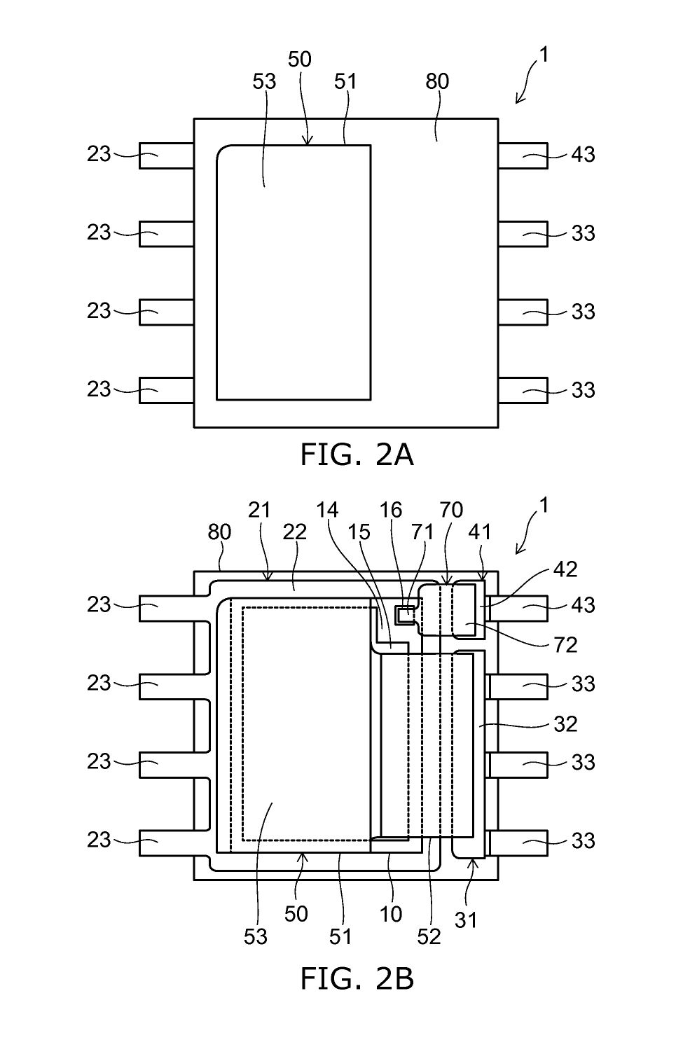

FIG. 2A is a schematic top view of the semiconductor device 1 of the embodiment. FIG. 2B is a schematic top view in which the resin 80 is removed. In FIG. 2B, with regard to the resin 80, only the outline of its side surface is depicted.

The semiconductor device 1 of the embodiment includes a semiconductor chip 10, lead frames 21, 31, 41 electrically connected to the semiconductor chip 10, a first connector 50, a second connector 70, and a resin 80 sealing these elements.

The semiconductor chip 10 is a vertical device in which a current path is formed in the vertical direction connecting between a first electrode provided on one surface side of the semiconductor layer and a second electrode provided on the other surface side. The semiconductor chip 10 is e.g. a vertical MOSFET (metal-oxide-semiconductor field effect transistor). Alternatively, the semiconductor chip 10 is a vertical IGBT (insulated gate bipolar transistor) or vertical diode.

Silicon is used as the semiconductor. Alternatively, semiconductors other than silicon (e.g., a compound semiconductor such as SiC and GaN) may be used.

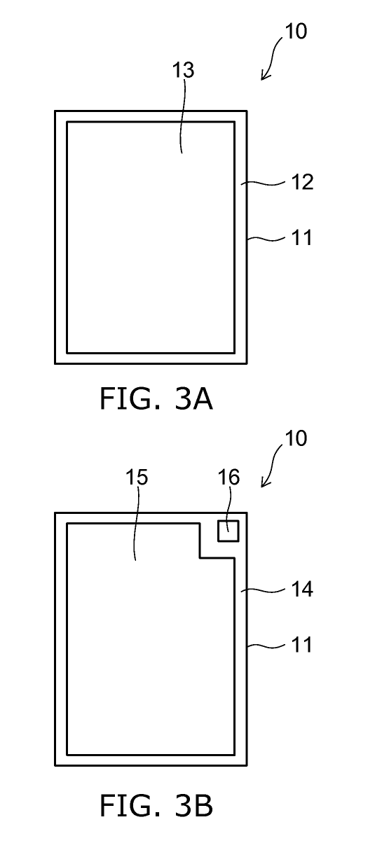

FIG. 3A is a schematic plan view of a first surface 12 of the semiconductor chip 10. FIG. 3B is a schematic plan view of a second surface 14 on the opposite side from the first surface 12.

As shown in FIG. 3A, a first electrode 13 is formed on the first surface 12 of the semiconductor layer 11. For instance, in a MOSFET, the first electrode 13 is a drain electrode. The first electrode 13 occupies a large portion of the first surface 12.

As shown in FIG. 3B, a second electrode 15 and a third electrode 16 are formed on the second surface 14 of the semiconductor layer 11 and insulated from each other. The second electrode 15 occupies a large portion of the second surface 14. For instance, in a MOSFET, the second electrode 15 is a source electrode. The area of the third electrode 16 is smaller than the area of the second electrode 15. For instance, in a MOSFET, the third electrode 16 is a gate electrode.

As shown in FIG. 2B, the first lead frame 21 includes a die pad 22 and a plurality of leads 23. The die pad 22 is formed in a quadrangular planar shape. The plurality of leads 23 are projected from one side of the die pad 22. The first lead frame 21 is shaped by stamping a metal plate. The die pad 22 and the leads 23 are integrated together.

A second lead frame 31 is provided on the opposite side from the projecting direction of the leads 23 of the first lead frame 21 and spaced from the first lead frame 21.

The second lead frame 31 includes an inner lead 32 provided on the first lead frame 21 side, and a plurality of outer leads 33 projected from the inner lead 32. The outer leads 33 are projected in the opposite direction from the projecting direction of the leads 23 of the first lead frame 21. The inner lead 32 extends in the direction orthogonal to the projecting direction of the outer leads 33 and the projecting direction of the leads 23 of the first lead frame 21.

The second lead frame 31 is shaped by stamping a metal plate. The inner lead 32 and the outer leads 33 are integrated together.

A third lead frame 41 is also provided on the opposite side from the projecting direction of the leads 23 of the first lead frame 21 and spaced from the first lead frame 21. The third lead frame 41 is provided longitudinally adjacent to the inner lead 32 of the second lead frame 31. The third lead frame 41 is spaced from the second lead frame 31.

The third lead frame 41 includes an inner lead 42 provided on the first lead frame 21 side, and one outer lead 43 projected from the inner lead 42. The outer lead 43 is projected in the same direction as the projecting direction of the outer leads 33 of the second lead frame 31.

As shown in FIG. 1, no step difference is formed between the lead 23 of the first lead frame 21 and the die pad 22. The upper surface of the lead 23 and the upper surface of the die pad 22 are connected flat. The lower surface of the lead 23 and the lower surface of the die pad 22 are connected flat.

The second lead frame 31 is bent in the portion between the inner lead 32 and the outer lead 33. Thus, a step difference is formed between the inner lead 32 and the outer lead 33. Like the second lead frame 31, the third lead frame 41 is also bent in the portion between the inner lead 42 and the outer lead 43. Thus, a step difference is formed between the inner lead 42 and the outer lead 43.

The lower surface of the outer lead 33 of the second lead frame 31 is located at the same height level as the lower surface of the first lead frame 21 (the lower surface of the lead 23 and the lower surface of the die pad 22). The lower surface of the outer lead 43 of the third lead frame 41 is located at the same height level as the lower surface of the first lead frame 21 and the lower surface of the outer lead 33 of the second lead frame 31.

With the lower surface of the outer leads 33, 43 and the lower surface of the first lead frame 21 taken as a reference in the height direction (vertical direction), the upper surface of the inner leads 32, 42 is located above the upper surface of the die pad 22.

The semiconductor chip 10 is mounted on the die pad 22 of the first lead frame 21. In the semiconductor chip 10, the first surface 12 with the first electrode 13 formed thereon is faced toward the die pad 22.

The first electrode 13 is bonded to the die pad 22 via a conductive bonding material (e.g., solder) 25 shown in FIG. 1. Thus, the first electrode 13 of the semiconductor chip 10 is electrically connected to the first lead frame 21.

A first connector (in a MOSFET, a source connector) 50 is mounted on the second surface 14 of the semiconductor chip 10. The first connector 50 includes a first portion 51 and a second portion 52. The first portion 51 and the second portion 52 are relatively different in thickness. The first portion 51 is thicker than the second portion 52.

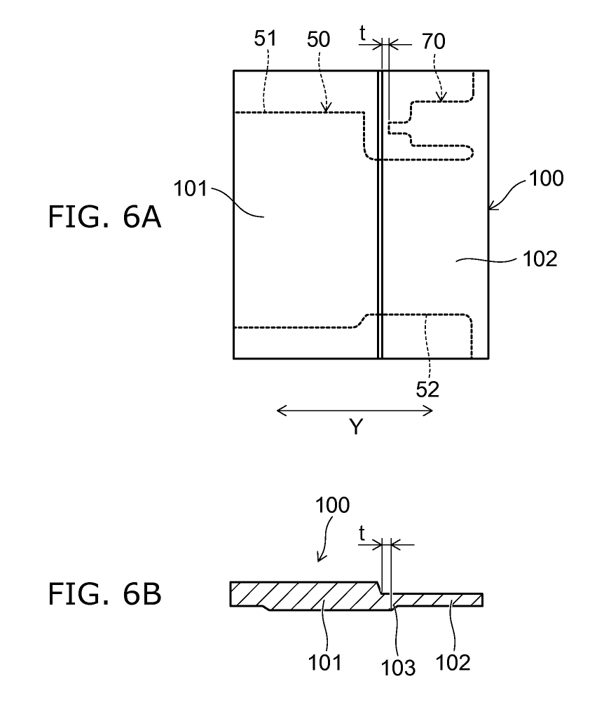

The first connector 50 is shaped by stamping a metal plate 100 shown in FIG. 6A described later. The first portion 51 and the second portion 52 are integrated together. The first connector 50 is made of e.g. copper, which is superior in electrical and thermal conduction. Alternatively, the first connector 50 may be made of a copper alloy composed primarily of copper.

The first portion 51 is thicker than the thickness of each lead frame 21, 31, 41. The thickness of the first portion 51 is e.g. 0.5 mm or more and 1 mm or less. The first portion 51 has a first bonding surface 54 bonded to the second electrode 15 of the semiconductor chip 10 via a conductive bonding material 55 such as solder. Furthermore, the first portion 51 has a heat dissipation surface 53 formed on the opposite side from the first bonding surface 54 and exposed from the resin 80.

The second portion 52 is projected from the first portion 51 toward the second lead frame 31. The tip part of the second portion 52 overlaps the inner lead 32 of the second lead frame 31, and is bonded to the upper surface of the inner lead 32 via a conductive bonding material 35 such as solder.

Thus, the first connector 50 electrically connects the second electrode 15 of the semiconductor chip 10 to the second lead frame 31.

As shown in FIG. 2B, the third electrode (gate electrode) 16 of the semiconductor chip 10 and the third lead frame 41 are electrically connected by a second connector (in a MOSFET, a gate connector) 70.

One end part 71 of the second connector 70 is bonded to the third electrode 16 via a conductive bonding material such as solder. The other end part 72 of the second connector 70 overlaps the inner lead 42 of the third lead frame 41, and is bonded to the upper surface of the inner lead 42 of the third lead frame 41 via a conductive bonding material such as solder.

The second connector 70 is shaped simultaneously with the first connector 50 by stamping the metal plate 100 shown in FIG. 6A described later. Thus, the second connector 70 is made of the same material as the first connector 50, e.g., copper or copper alloy.

The thickness of the second connector 70 is equal to the thickness of the second portion 52 of the first connector 50. That is, as described later, the relatively thin portion of the metal plate 100 is used to form the second connector 70 and the second portion 52 of the first connector 50. The relatively thick portion of the metal plate 100 constitutes the first portion 51 of the first connector 50.

The aforementioned conductive bonding material is not limited to solder, but may be a conductive paste such as silver paste.

The semiconductor chip 10 is resin sealed and protected from the external environment. The resin 80 covers the semiconductor chip 10, the upper surface of the die pad 22, the inner lead 32 of the second lead frame 31, the inner lead 42 of the third lead frame 41, the side surface of the first portion 51 of the first connector 50, the second portion 52 of the first connector 50, and the second connector 70.

Furthermore, the resin 80 covers the bonding part between the first electrode 13 and the die pad 22, the bonding part between the second electrode 15 and the first connector 50, the bonding part between the second portion 52 of the first connector 50 and the inner lead 32 of the second lead frame 31, the bonding part between the third electrode 16 and the second connector 70, and the bonding part between the second connector 70 and the inner lead 42 of the third lead frame 41.

The lower surface of the first lead frame 21 (the lower surface of the lead 23 and the lower surface of the die pad 22), the lower surface of the outer lead 33 of the second lead frame 31, and the lower surface of the outer lead 43 of the third lead frame 41 are not covered with the resin 80, but exposed from the resin 80.

The lower surface of the first lead frame 21, the lower surface of the outer lead 33 of the second lead frame 31, and the lower surface of the outer lead 43 of the third lead frame 41 are bonded to the conductor pattern of the mounting substrate (wiring substrate), not shown, via e.g. solder.

As shown in FIGS. 1 and 2A, the upper surface of the first portion 51 of the first connector 50 is exposed from the resin 80 and functions as a heat dissipation surface 53. A heat sink can be bonded as necessary onto the heat dissipation surface 53 of the first connector 50.

Heat generated in the semiconductor chip 10 is dissipated to the mounting substrate through the die pad 22 having a larger area than the first electrode 13. Furthermore, the heat is dissipated to the outside of the semiconductor device 1 (e.g., into the air) through the heat dissipation surface 53 of the first connector 50. That is, the semiconductor device 1 of the embodiment has a double-sided heat dissipation package structure. Thus, the heat dissipation performance can be enhanced particularly in the case of power applications in which the amount of chip heat generation is likely to increase.

The first portion 51 of the first connector 50 serves not only for electrical connection between the semiconductor chip 10 and the second lead frame 31, but also as a heat dissipator responsible for heat dissipation to the opposite side from the mounting surface. The first portion 51 of the first connector 50 is mounted directly above the semiconductor chip 10. The ratio of the area of the bonding surface between the second electrode 15 and the first portion 51 to the area of the second electrode 15 of the semiconductor chip 10 is 80% or more. The ratio of the area of the heat dissipation surface 53 of the first connector 50 to the area of the second electrode 15 of the semiconductor chip 10 is 100% or more.

That is, a large portion of the surface of the second electrode 15 is used as a surface for thermal conduction to the first connector 50. The heat conducted to the first connector 50 is dissipated from the heat dissipation surface 53 having a larger area than the second electrode 15 to the outside of the semiconductor device 1. Thus, the first connector 50 can be effectively used as a heat dissipator, achieving high heat dissipation efficiency.

The first connector 50 is thickened not entirely, but provided with the second portion 52 thinner than the first portion 51. This provides a region in which the resin 80 covers the first connector 50 from the upper surface side. That is, in the second portion 52, the resin 80 covers the upper surface of the first connector 50. Thus, in this structure, the second portion 52 bites into the resin 80. This can suppress peeling of the resin 80 (coming off of the first connector 50) compared with the structure in which the upper surface of the first connector 50 is entirely exposed from the resin 80.

The first connector 50 has a structure in which the first portion 51 and the second portion 52 relatively different in thickness are integrated together. The second connector (gate connector) 70 connected to the third electrode (gate electrode) 16 does not function as a heat dissipator exposed from the resin 80. The current flowing therein is smaller than that in the first connector (source connector) 50 connected to the second electrode (source electrode) 15. Thus, the second connector 70 is not required to be as thick as the first portion 51 of the first connector 50 functioning also as a heat dissipator. Thickening the second connector 70 more than necessary incurs the increase of material cost.

Here, the method of fabricating the first connector 50 and the second connector 70 from separate metal plates can be considered as a comparative example. That is, the first connector 50 can be fabricated from a deformed metal plate including a thick portion constituting the first portion 51 and a thin portion constituting the second portion 52. The second connector 70 can be fabricated from a metal plate having a uniform thickness like a typical lead frame.

However, in this case, the material efficiency is low because two kinds of metal plates are used, i.e., the metal plate for the first connector 50 and the metal plate for the second connector 70. Furthermore, the first connector 50 and the second connector 70 are formed in separate frames. Thus, mounting of the first connector 50 and mounting of the second connector 70 also need to be separately performed.

According to the embodiment, the first connector 50 and the second connector 70 are shaped simultaneously from the same metal plate by devising a new layout of the first connector 50 and the second connector 70.

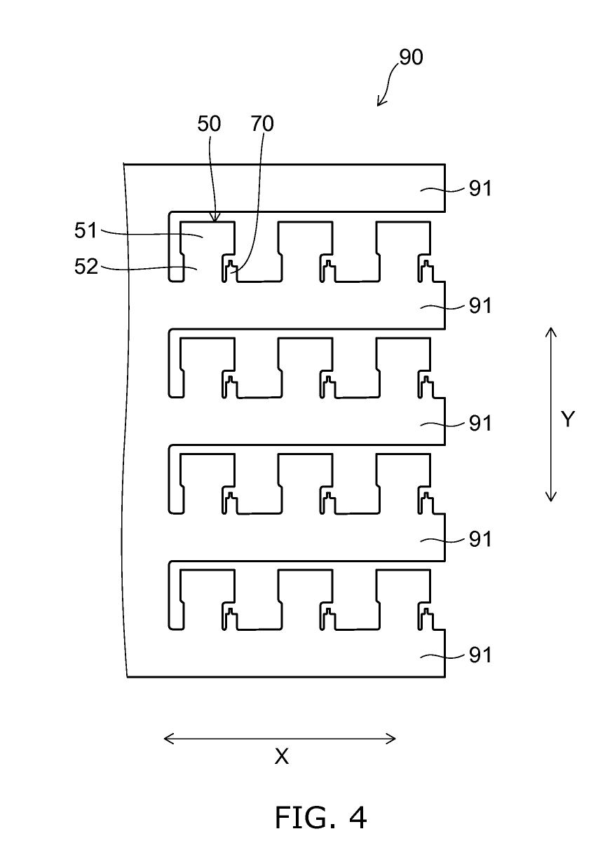

FIG. 4 is a schematic plan view of a connector frame 90 of the embodiment in which the first connector 50 and the second connector 70 are shaped.

The first connector 50 and the second connector 70 are integrated with a frame part 91. The frame part 91 extends in a first direction (X-direction). The first connector 50 and the second connector 70 are projected from the frame part 91 in a second direction (Y-direction) orthogonal to the first direction (X-direction).

A plurality of first connectors 50 are arranged at an equal pitch in the X-direction. A plurality of second connectors 70 are arranged at an equal pitch in the X-direction. The spacings (X-direction spacing and Y-direction spacing) between the first connector 50 and the second connector 70 are constant.

The frame part 91, the second portion 52 of the first connector 50, and the second connector 70 have the same thickness. The second portion 52 of the first connector 50 and the second connector 70 are directly provided on the frame part 91.

The first portion 51 of the first connector 50 and the frame part 91 sandwich the second portion 52 and the second connector 70 in the Y-direction.

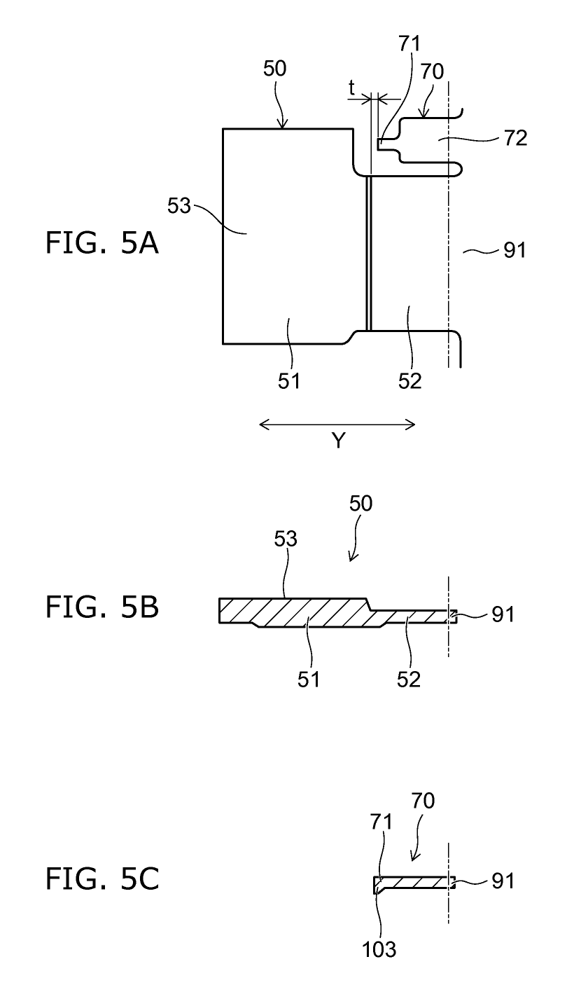

FIG. 5A shows an enlarged view of one first connector 50 and one second connector 70 in FIG. 4.

FIG. 5B is a sectional view taken along the Y-direction of the first connector 50 shown in FIG. 5A. FIG. 5C is a sectional view taken along the Y-direction of the second connector 70 shown in FIG. 5A.

The first connector 50 and the second connector 70 are cut at the position indicated by the double-dot dashed line in FIGS. 5A to 5C, and are separated from the frame part 91.

The connector frame 90 is fabricated by stamping a metal plate 100 shown in FIG. 6A using a die. FIG. 6B shows a cross section taken along the Y-direction of the metal plate 100 shown in FIG. 6A. FIGS. 6A and 6B show a portion of the strip-shaped metal plate 100 in which a thick portion 101 and a thin portion 102 thinner than the thick portion 101 are formed by rolling.

The metal plate 100 is e.g. a copper plate or a plate of a copper alloy. First, the metal plate 100 having a uniform thickness is rolled with a roller and shaped like a strip. At this time, the portion to be thinned is thinned by the roller for locally crushing the portion. This step is repeated a plurality of times. Thus, the metal plate 100 is shaped into a desired shape.

Subsequently, the metal plate 100 is stamped. Thus, as shown by dashed lines in FIG. 6A, a first connector 50 and a second connector 70 are shaped. Part of the thick portion 101 in the metal plate 100 is left as a first portion 51 of the first connector 50. Part of the thin portion 102 in the metal plate 100 is left as a second portion 52 of the first connector 50 and a second connector 70.

According to the embodiment described above, the first connector 50 and the second connector 70 are fabricated from the same metal plate 100. This is superior in material efficiency to fabricating them from separate metal plates.

In the state of the connector frame 90, the X-direction pitch of the second portion 52 of the first connector 50 and the second connector 70 and the Y-direction pitch of the first portion 51 of the first connector 50 and the second connector 70 are made equal to the pitches used in actual mounting on the semiconductor chip 10 and the frames 31, 41.

Thus, in the state of the connector frame 90 before separation into the first connector 50 and the second connector 70, the first connector 50 and the second connector 70 can be simultaneously mounted on the semiconductor chip 10 and the frames 31, 41. This improves the production efficiency.

The distance t between the end on the second portion 52 side of the first portion 51 of the first connector 50 and the tip in the projecting direction of the second connector 70 is 0.2 mm or more.

In stamping the metal plate 100, accuracy in shape and dimension is likely to decrease at the boundary between the thick portion 101 and the thin portion 102. Thus, according to the embodiment, the metal plate 100 is stamped so that the tip of the second connector 70 is located at a distance t of 0.2 mm or more from the boundary between the thick portion 101 and the thin portion 102 in the metal plate 100. This can suppress the deformation and the decrease of dimensional accuracy in the tip part of the second connector 70 bonded to the third electrode 16.

Stamping is performed so that a thick portion 103 is slightly left in the tip part of the thin portion 102 constituting the second connector 70 as shown in FIGS. 6B and 5C. The thick portion 103 projected downward is used for bonding to the third electrode (gate electrode) 16. Thus, the lower part 103 of the one end part 71 of the second connector 70 can be bonded to the third electrode 16 without bending the second connector 70. Bending work of the small second connector 70 may be difficult, but such bending work is not needed in the embodiment.

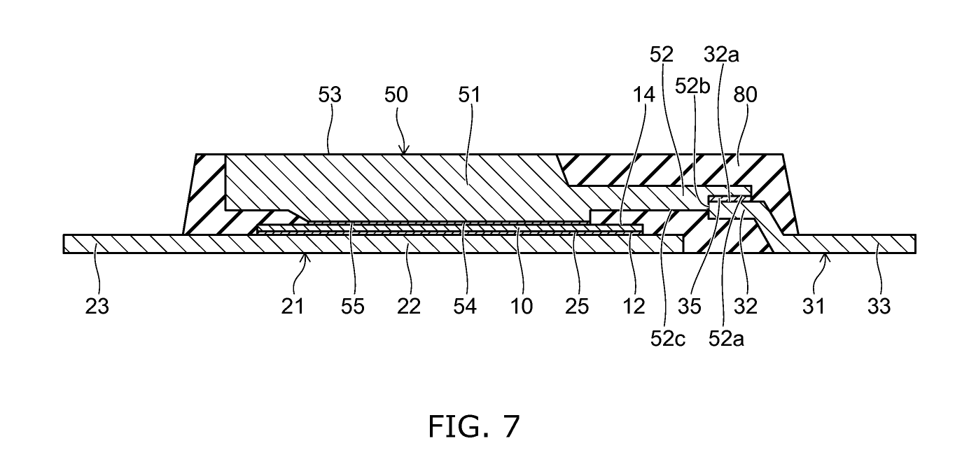

FIG. 7 is a schematic sectional view of a semiconductor device of an alternative embodiment.

As shown in FIG. 7, the lower surface (second bonding surface) 52a of the tip part of the second portion 52 overlaps the inner lead 32 of the second lead frame 31. In the second portion 52 of the first connector 50, a first step difference part 52b is provided between the second bonding surface 52a and the lower surface 52c.

The second bonding surface 52a of the first connector 50 is placed via a bonding material 35 on the upper surface 32a of the inner lead 32 of the second lead frame 31. In this state, the bonding material 35 is melted. At this time, the end part of the inner lead 32 of the second lead frame 31 abuts on the side surface of the first step difference part 52b. This restrains misalignment of the first connector 50 in the lateral direction in FIG. 7. The suppression of misalignment of the first connector 50 improves the reliability of electrical connection between the semiconductor chip 10 and the second lead frame 31 via the first connector 50.

Also in the embodiment shown in FIG. 7, as in the aforementioned embodiment, the first connector 50 and the second connector 70 are simultaneously shaped from the same metal plate. This is superior in material efficiency to fabricating the first connector 50 and the second connector 70 from separate metal plates.

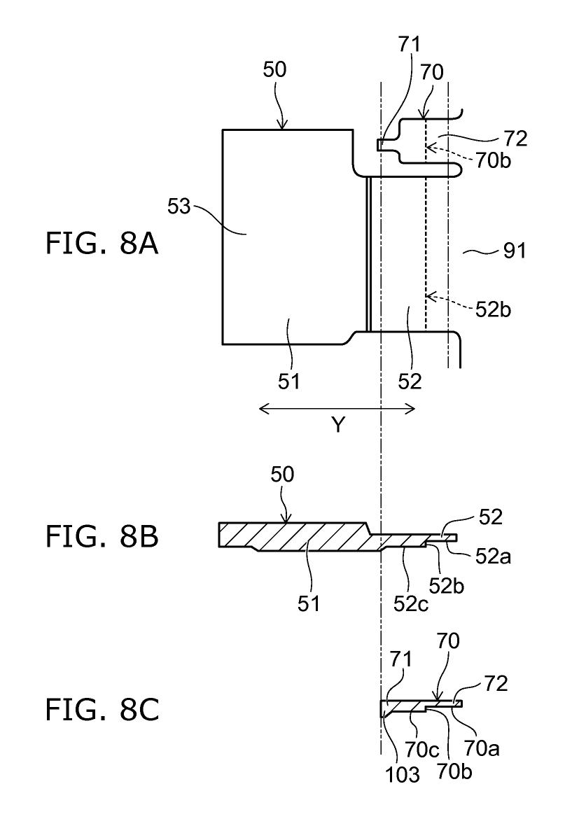

FIG. 8A is a schematic plan view enlarging a connector frame in which the first connector 50 and the second connector 70 in the semiconductor device of the embodiment shown in FIG. 7 are shaped. FIG. 8B is a sectional view taken along the Y-direction of the first connector 50 shown in FIG. 8A. FIG. 8C is a sectional view taken along the Y-direction of the second connector 70 shown in FIG. 8A.

As shown in FIGS. 8A and 8B, the first step difference part 52b extends continuously in e.g. the direction orthogonal to the projecting direction of the second portion 52.

As shown in FIGS. 8A and 8C, a third bonding surface 70a bonded to the inner lead 42 of the third lead frame 41 shown in FIG. 2B is provided at the lower surface on the other end part 72 side of the second connector 70.

The second connector 70 is formed simultaneously with the first connector 50. Thus, a second step difference part 70b like the first step difference part 52b of the first connector 50 is provided also between the third bonding surface 70a and the lower surface 70c in the second connector 70. The second step difference part 70b extends continuously in e.g. the direction orthogonal to the projecting direction of the second connector 70.

Thus, the end part of the inner lead 42 of the third lead frame 41 abuts on the side surface of the second step difference part 70b. This restrains misalignment of the second connector 70 like the first connector 50. The suppression of misalignment of the second connector 70 improves the reliability of electrical connection between the semiconductor chip 10 and the third lead frame 41 via the second connector 70.

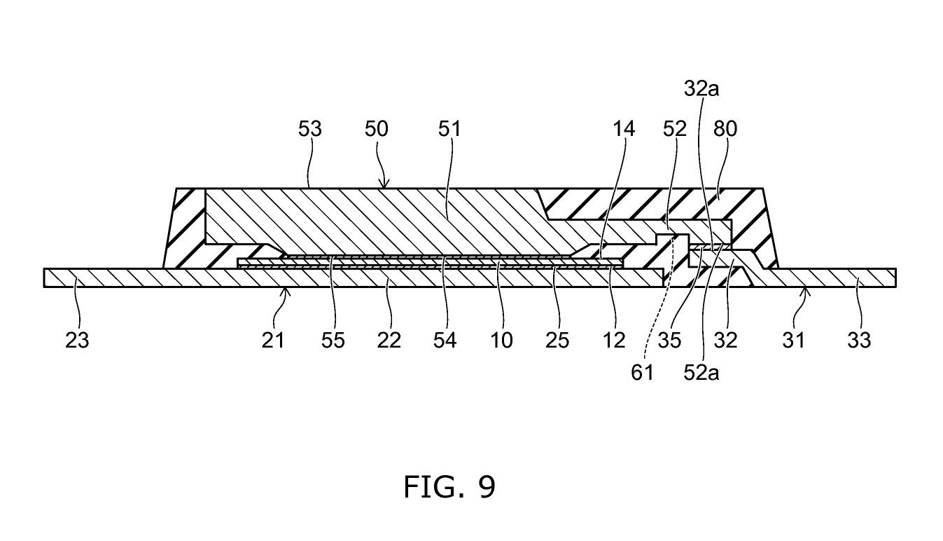

FIG. 9 is a schematic sectional view of a semiconductor device of a further alternative embodiment.

At the lower surface of the second portion 52 of the first connector 50, a first groove 61 is provided as a first recess depressed toward the upper surface of the second portion 52.

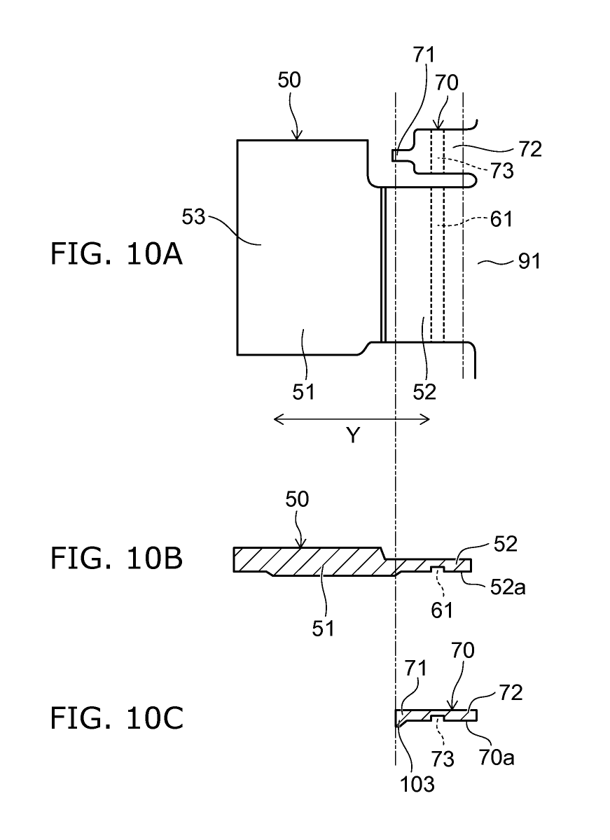

FIG. 10A is a schematic plan view enlarging a connector frame in which the first connector 50 and the second connector 70 in FIG. 9 are shaped. FIG. 10B is a sectional view taken along the Y-direction of the first connector 50 shown in FIG. 10A. FIG. 10C is a sectional view taken along the Y-direction of the second connector 70 shown in FIG. 10A.

As shown in FIGS. 10A and 10B, the first groove 61 extends continuously in e.g. the direction orthogonal to the projecting direction of the second portion 52.

As shown in FIGS. 10A and 10C, a third bonding surface 70a bonded to the inner lead 42 of the third lead frame 41 shown in FIG. 2B, and a second groove 73 as a second recess depressed toward the upper surface of the second connector 70, are provided at the lower surface of the second connector 70. The second groove 73 extends continuously in e.g. the direction orthogonal to the projecting direction of the second connector 70.

Also in the embodiment shown in FIGS. 9, 10A to 10C, the second connector 70 is formed simultaneously with the first connector 50. Thus, the first groove 61 of the first connector 50 and the second groove 73 of the second connector 70 are simultaneously formed.

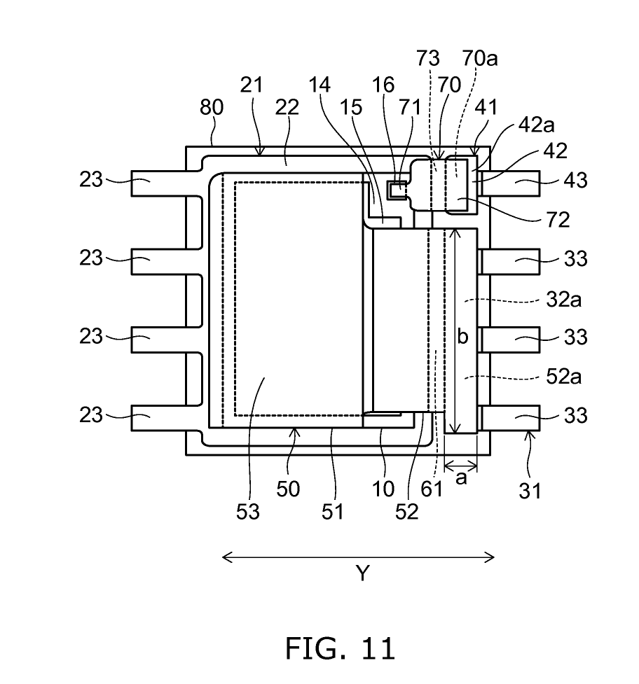

FIG. 11 is a schematic top view of the semiconductor device of FIG. 9 in which the resin 80 is removed. In FIG. 11, with regard to the resin 80, only the outline of its side surface is depicted.

The first groove 61 of the first connector 50 is provided close to the second bonding surface 52a on the first portion 51 side of the second bonding surface 52a. The first groove 61 does not overlap the upper surface 32a of the inner lead 32 of the second lead frame 31, but is formed on the first lead frame 21 side of the inner lead 32.

The second groove 73 of the second connector 70 is provided close to the third bonding surface 70a on the one end part 71 side of the third bonding surface 70a. The second groove 73 does not overlap the upper surface 42a of the inner lead 42 of the third lead frame 41, but is formed on the first lead frame 21 side of the inner lead 42.

Forming the first groove 61 and the second groove 73 achieves the effect of self-alignment when the bonding material 35 is melted.

More specifically, the first groove 61 is formed close to the second bonding surface 52a of the first connector 50. This restricts the width (Y-direction width) of the second bonding surface 52a.

This first groove 61 suppresses that the melted bonding material 35 wets and spreads on the lower surface of the second portion 52 of the first connector 50 toward the first portion 51. This suppresses Y-direction misalignment of the second portion 52.

The suppression of misalignment of the second portion 52 with respect to the second lead frame 31 can suppress the entire misalignment of the first connector 50, and also suppress misalignment of the first portion 51 with respect to the semiconductor chip 10.

Likewise, the second groove 73 is formed close to the third bonding surface 70a of the second connector 70. This restricts the width (Y-direction width) of the third bonding surface 70a.

This second groove 73 suppresses that the melted bonding material wets and spreads on the lower surface of the second connector 70. This suppresses Y-direction misalignment of the second connector 70.

Furthermore, as shown in FIG. 11, the second bonding surface 52a of the first connector 50 and the upper surface 32a of the inner lead 32 of the second lead frame 31 can be made equal in the width a in the projecting direction (Y-direction) of the second portion 52. Then, the melted bonding material 35 does not spread in the width direction beyond the width a. This avoids misalignment in the width direction of the second portion 52 of the first connector 50.

Forming the aforementioned first groove 61 can easily match the width of the second bonding surface 52a with the width of the upper surface 32a of the second lead frame 31.

Furthermore, the second bonding surface 52a and the upper surface 32a of the inner lead 32 of the second lead frame 31 can be made equal in the length b in the direction orthogonal to the projecting direction of the second portion 52. Then, the melted bonding material 35 does not spread in the length direction beyond the length b. This avoids misalignment in the length direction of the second portion 52 of the first connector 50.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A connector frame comprising:
a frame part;
a first connector projected from the frame part and integrated with the frame part, the first connector including a first portion and a second portion provided between the first portion and the frame part, the second portion being thinner than the first portion; and
a second connector projected from the frame part and integrated with the frame part, the second connector being as thick as the second portion of the first connector.

2. The connector frame according to claim 1, wherein a distance between an end on the second portion side of the first portion of the first connector and a tip in a projecting direction of the second connector is 0.2 mm or more.

3. The connector frame according to claim 1, wherein
the frame part extends in a first direction,
the first connector and the second connector are projected in a second direction orthogonal to the first direction, and
a plurality of the first connectors are arranged at an equal pitch in the first direction, and a plurality of the second connectors are arranged at an equal pitch in the first direction.

4. The connector frame according to claim 1, wherein a thickness of the frame part is equal to a thickness of the second portion of the first connector and a thickness of the second connector.

5. The connector frame according to claim 1, wherein the connector frame includes copper.

6. A semiconductor device comprising:
a first lead frame;
a second lead frame provided to be separated from the first lead frame;
a third lead frame provided to be separated from the first lead frame and the second lead frame;
a semiconductor chip provided on the first lead frame, the semiconductor chip including a semiconductor layer having a first surface and a second surface opposite to the first surface, a first electrode provided on the first surface and bonded to the first lead frame, a second electrode provided on the second surface, and a third electrode provided on the second surface;
a resin sealing the semiconductor chip;
a first connector including:
a first portion provided on the second surface of the semiconductor chip and bonded to the second electrode, the first portion including a first bonding surface bonded to the second electrode of the semiconductor chip and a heat dissipation surface being opposite to the first bonding surface and exposed from the resin; and
a second portion made of same material as the first portion and integrated with the first portion, the second portion projected from the first portion toward the second lead frame and bonded to the second lead frame, the second portion being thinner than the first portion; and
a second connector connecting the third electrode of the semiconductor chip with the third lead frame, the second connector made of the same material as the first connector, and being as thick as the second portion.

7. The semiconductor device according to claim 6, wherein the first connector and the second connector include copper.

8. The semiconductor device according to claim 6, wherein a ratio of an area of the heat dissipation surface to an area of the second electrode is 100% or more.

9. The semiconductor device according to claim 6, wherein the second portion is covered with the resin.

10. The semiconductor device according to claim 6, wherein a thickness of the first portion is 0.5 millimeters or more and 1 millimeter or less.

11. The semiconductor device according to claim 6, wherein
the second portion of the first connector has:
a second bonding surface overlapping the second lead frame; and
a first step difference part provided near the second bonding surface at the first portion side, and
the second connector has:
a third bonding surface overlapping the third lead frame; and
a second step difference part provided near the third bonding surface.

12. The semiconductor device according to claim 11, wherein
a first recess is provided at a lower surface of the second portion near the second bonding surface, and the first step difference part is provided between the first recess and the second bonding surface, and
a second recess is provided at a lower surface of the second connector near the third bonding surface, and the second step difference part is provided between the second recess and the third bonding surface.

13. The semiconductor device according to claim 11, wherein the second bonding surface of the first connector and an upper surface of the second lead frame bonded to the second bonding surface are equal in width in a projecting direction of the second portion.

14. The semiconductor device according to claim 11, wherein the second bonding surface of the first connector and an upper surface of the second lead frame bonded to the second bonding surface are equal in length in a direction orthogonal to a projecting direction of the second portion.

15. The semiconductor device according to claim 12, wherein the first recess and the second recess are grooves extending in a direction orthogonal to a projecting direction of the second portion.
